(19) United States
(12) Patent Application Publication
(10) Pub. No.: US 2014/0202734 A1
(43) Pub. Date: Jul. 24, 2014

(54) Transparent Conductive Film, Method of Manufacturing the Same, and Touch Panel Having the Same

(71) Applicants: Sang A Ju, Seoul (KR); Kyoung Ho Kim, Seoul (KR)

(72) Inventors: Sang A Ju, Seoul (KR); Kyoung Ho Kim, Seoul (KR)

(73) Assignee: LG INNOTEK CO., LTD., Seoul (KR)

(21) Appl. No.: 14/342,728

(22) PCT Filed: Sep. 6, 2012
(86) PCT No.: PCT/KR2012/007150

§ 371 Date: Mar. 4, 2014

(30) Foreign Application Priority Data
Sep. 6, 2011 (KR) 10-2011-0090382

(51) Int. Cl. H01B 1/12; H05K 3/12

(52) U.S. Cl. CPC H01B 1/12; H05K 3/12
USPC 174/126.1; 427/108; 428/419

(57) ABSTRACT

Provided are a transparent conductive film, a method of manufacturing the same, and a touch panel having the same, the transparent conductive film including: a transparent film; and a conductive layer formed on one surface of the transparent film, wherein the conductive layer includes a linear interconnecting structure layer and a PEDOT(poly-3,4-ethylene dioxythiophene)-PSS(polystyrenesulfonate) layer. In accordance with the present invention, it can be provided with the conductive film, which has improved haze and non-resistant properties, excellent flexibility, and low costs by economic processes, even without a structural change of the transparent conductive film, and the touch panel and the display using the same.

### CROSS-REFERENCE TO RELATED APPLICATIONS

This application is the U.S. national stage application of International Patent Application No. PCT/KR2012/007150, filed Sep. 6, 2012, which claims priority to Korean Application No. 10-2011-0090382, filed Sep. 6, 2011, the disclosures of each of which are incorporated herein by reference in their entirety.

### TECHNICAL FIELD

The present invention relates to a transparent conductive film, a method of manufacturing the same, and a touch panel having the same.

### BACKGROUND ART

A transparent conductive film is called a film having transparency and conductivity in a visible ray area by forming a transparent conductive layer such as ITO (Indium Tin Oxide) on one surface of a glass substrate or a plastic film. The transparent conductive film has been widely used in a touch panel and the like.

An important performance of the transparent conductive film is conductivity and transparency. When the conductivity decreases, it would be difficult to perform smooth drive, and when the transparency is deteriorated, a display performance decreases. Furthermore, as the uses and shapes of devices to which a touch panel using the transparent conductive film is applied have been recently varied, the touch panel as well as the devices themselves has been also required to have flexibility.

However, in the case of a film which mainly uses ITO (Indium Tin Oxide) as a conductive layer, since the layer is composed of an inorganic substance, a bending property of the film is weak. Thus, it would be disadvantageous to realize the flexibility of a complete product. Moreover, because the indium is a scarce metal, it is worried that natural resources can be exhausted in the future.

Thus, efforts to solve such a problem have been continuously made recently by combining film processing technologies with ink related technologies including silver (Ag) nanowires having a large aspect ratio and a linear structure as high transparent and high conductive interconnecting structure.

In the case of forming of a coating layer using the ink including the linear interconnecting structure, it is advantageous that a thickness of the coating layer can be controlled, the coating layer can be laminated as multi layers, and a price can be reduced. Thus, researches on a technology to replace the ITO with the ink are in process. However, haze and non-resistant values of the coating layer using the linear interconnecting structure ink have not realize a performance which is so useful as the ITO can be replaced with the linear interconnecting structure ink. Accordingly, researches on a technology to solve it have been urgently required.

### DISCLOSURE OF INVENTION

### Technical Problem

The present invention has been made keeping in mind the above problems, and an aspect of the present invention provides a conductive film having improved haze and non-resistant properties, excellent flexibility, and a low cost by further including a PEDOT coating layer of a conductive polymer on a linear interconnecting structure coating layer.

Another aspect of the present invention provides a method of manufacturing the conductive film.

### Solution to Problem

According to an aspect of the present invention, there is provided a transparent conductive film including: a transparent film; and a conductive layer formed on one surface of the transparent film, wherein the conductive layer includes a linear interconnecting structure layer and a PEDOT(poly-3,4-ethylene dioxythiophene)-PSS(polystyrenesulfonate) layer.

The linear interconnecting structure layer may be formed on one surface of the transparent film, and the PEDOT(poly-3,4-ethylene dioxythiophene)-PSS(polystyrenesulfonate) layer may be formed on the linear interconnecting structure layer.

Furthermore, the linear interconnecting structure layer may be composed of two or more multi layers.

Also, the PEDOT(poly-3,4-ethylene dioxythiophene)-PSS(polystyrenesulfonate) layer may be composed of two or more multi layers.

Also, the linear interconnecting structure layer may have a thickness of 5 to 10 μm before it becomes dry.

Also, the PEDOT(poly-3,4-ethylene dioxythiophene)-PSS(polystyrenesulfonate) layer may have a thickness of 5 to 10 μm before it becomes dry.

Furthermore, the PEDOT(poly-3,4-ethylene dioxythiophene)-PSS(polystyrenesulfonate) layer may contain PEDOT(poly-3,4-ethylene dioxythiophene) and PSS(polystyrenesulfonate) in a ratio of 1:1.

Also, the PEDOT(poly-3,4-ethylene dioxythiophene)-PSS(polystyrenesulfonate) layer further may include a surfactant.

Also, the linear interconnecting structure layer may further include a thickener and a surfactant.

According to another aspect of the present invention, there is further provided a touch panel including the transparent conductive film.

Furthermore, according to still another aspect of the present invention, there is further provided a display device including the touch panel.

The display device may be an LCD device, a PDP, an LED, an OLED or an E-paper device.

Meanwhile, according to still another aspect of the present invention, there is further provided a method of manufacturing a transparent conductive film including forming a conductive layer including a linear interconnecting structure layer and a PEDOT(poly-3,4-ethylene dioxythiophene)-PSS (polystyrenesulfonate) layer on one surface of a transparent film.

The forming of the conductive layer may include: forming the linear interconnecting structure layer on any one surface the transparent film; and forming the PEDOT-PSS layer on the linear interconnecting structure layer.

Furthermore, the forming of the linear interconnecting structure layer may be performed by coating any one surface of the transparent film with an ink including linear interconnecting structure, water, a thickener and a surfactant, and provisionally drying it for 5 to 40 seconds at a temperature of 100° C. to 160° C.:

Furthermore, the forming of the linear interconnecting structure layer may be performed more than one time.

Furthermore, the forming of the PEDOT-PSS layer may be performed by coating the linear interconnecting structure layer with a PEDOT aqueous dispersion including PEDOT, PSS, water and a surfactant, and drying it for 5 to 40 seconds at the temperature of 100° C. to 160° C.

Also, the forming of the PEDOT-PSS layer may be performed more than one time.

The method of manufacturing the transparent conductive film may further include drying the film after the forming of the conductive layer including the linear interconnecting structure layer and the PEDOT-PSS layer. Furthermore, the drying of the film may be performed for 5 to 40 seconds at the temperature of 100° C. to 160° C.

### Advantageous Effects of Invention

In accordance with the present invention, it can be provided with the conductive film, which has excellent flexibility and a low cost while having improved haze and non-resistant properties due to the economical processes even without any structural change of the transparent conductive film, and the touch panel and display using the same.

### BRIEF DESCRIPTION OF DRAWINGS

The accompanying drawings are included to provide a further understanding of the present invention, and are incorporated in and constitute a part of this specification. The drawings illustrate exemplary embodiments of the present invention and, together with the description, serve to explain principles of the present invention. In the drawings:

FIG. 1 is a view for explaining the configuration of a transparent conductive film according to an exemplary embodiment of the present invention.

### BEST MODE FOR CARRYING OUT THE INVENTION

Exemplary embodiment according to the present invention will now be described more fully hereinafter with reference to the accompanying drawings. The exemplary embodiment of the present invention may, however, be embodied in many different forms and should not be construed as limited to the embodiment set forth herein. Rather this exemplary embodiment is provided so that this disclosure will be thorough and complete, and will fully convey the scope of the invention to those skilled in the art. Furthermore, when it is determined that specific descriptions regarding publicly known relevant functions or configurations may unnecessarily be beside main points of the present invention, corresponding descriptions are omitted. It will be further understood that terms used herein should be interpreted as having a meaning that is consistent with their meaning in the context of this specification. With regard to the elements which perform similar functions and operations, like numbers refer to like elements through the specification.

Hereinafter, the present invention will be explained in more detailed with reference to the drawing.

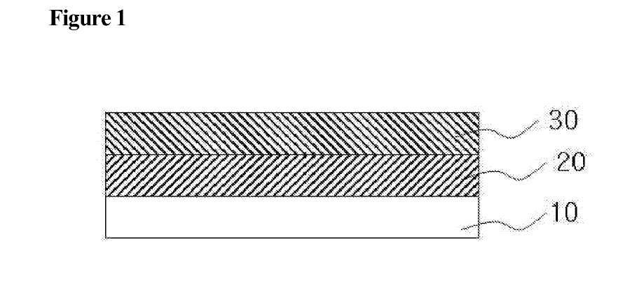

FIG. 1 is a view showing an exemplary embodiment of a transparent conductive film of the present invention.

As illustrated in FIG. 1, the transparent conductive film of the present invention may include a transparent film 10 and a conductive layer 20, 30 laminated on the transparent film.

At this time, the conductive layer may include a linear interconnecting structure layer 20 and a PEDOT(poly-3,4-ethylene dioxythiophene)-PSS(polystyrenesulfonate) layer 30. And also through this specification, the “linear interconnecting structure” means materials having large aspect ratio and linear-shape such as nanowires, nanorods or nanotubes.

The transparent film 10 may provides a formation surface of the conductive layer and mechanical strength, and may function to support the conductive layer and the transparent layer. Furthermore, the transparent film 10 may be all films having transparency such as glass and transparent polymer films, and its material or its quality of the material is not specially limited.

For example, the transparent film of the present invention may use a plastic film or glass and the like selected from a group consisting of polyacrylic, polyurethane, polyester, poly-epoxy, polyolefin, polycarbonate and cellulose.

A thickness of the transparent film may be in a range of about 20 to 1000 μmin the light of mechanical strength. When the thickness of the transparent film is less than 20 μm, the transparent film lacks the mechanical strength, and it would be hard to deal with it during a process work for forming the conductive layer and the like. When the transparent film having a thickness of more than 1000 μm is applied to a touch panel, it is problematic that a spot characteristic is bad, and the thickness of a product becomes thick, thereby reducing transmittance.

Meanwhile, the conductive layer according to the present exemplary embodiment of the invention may include a linear interconnecting structure layer and a PEDOT-PSS layer. In particular, the linear interconnecting structure layer may be formed on one surface of the transparent film, and the PEDOT-PSS layer may be formed on the linear interconnecting structure layer.

The linear interconnecting structure layer may be used a material with linear structures such as nanowires, nanorods or nanotube. The material may be a metal such as gold (Au), silver (Ag) or nickel (Ni), a conductive metal oxide such as zinc oxide, or carbon. The linear interconnecting structure layer may include a linear interconnecting structure having a diameter of about 10 to 50 μm, and a length of 10 to 40 μm.

Additives such as a thickener or a surfactant may be further included.

The linear interconnecting structure layer may be formed by coating the conductive layer with a linear interconnecting structure ink, and drying it. And also through this specification, the “linear interconnecting structure ink” means an ink including linear interconnecting structure.

The linear interconnecting structure ink may a linear interconnecting structure layer of 0.05 to 0.5 wt %, a thickener of 0.5 to 1 wt %, a surfactant of 0.0001 to 0.001 wt %, and water of 98 to 99.5 wt %.

When the linear interconnecting structure is included in the range of less than 0.05 wt %, it is problematic that conductivity of the layer is deteriorated. When the linear interconnecting structure is included in the range of more than 0.5 wt %, it is problematic that haze and milkiness are generated.

The linear interconnecting structure ink may be formed using a method of forming the conductive layer which was well known in the relevant technical field, for example, a vacuum deposition method, a sputtering method, an ion plating method, a spray heat decomposition method, a chemical plating method, an electro-plating method, a wet coating method, a bar coating method or a combination thereof.

Among these methods, in particular, the bar coating method may be used in the light of a formation speed and productivity of the linear interconnecting structure.

At this time, a coating thickness of the linear interconnecting structure ink before it becomes dry may be formed in a range of 5 to 10 μm. When the coating thickness is formed in the range of less than 5 μm, a contact of the linear interconnecting structure is not well performed, thereby reducing conductivity. When the coating thickness is formed in the range of less than 10 μm, a content of the linear interconnecting structure is high, thereby causing the problem of haze.

By such a method, the linear interconnecting structure ink coated on the transparent film is formed as the layer through drying it.

At this time, the drying may be performed by provisionally drying it for 5 to 40 seconds at a temperature of 100° C. to 160° C.

The transparent conductive film according to the present exemplary embodiment of the invention may include the linear interconnecting structure which is formed as multi layers by coating the film with the linear interconnecting structure ink and drying it more than one time, several times.

Meanwhile, in the present invention, the PEDOT-PASS layer is formed on the linear interconnecting structure layer formed by the method as described above.

The PEDOT(poly-3,4-ethylene dioxythiophene)-PSS(polystyrenesulfonate) layer may be produced by coating the linear interconnecting structure layer with an aqueous dispersion including PEDOT(poly-3,4-ethylene dioxythiophene) and PSS(polystyrenesulfonate) which are polymers having excellent conductivity, and drying it.

In general, the PEDOT is not melted in almost all solvents. However, if the PSS as an opposite ion is used, it may be dispersed in water. The PSS operates as a very good oxidant, a charge compensator, and a plate for polymerization. Thus, the PEDOT and PSS may be contained in the aqueous dispersion in a ratio of 70:30 to 30:70. In particular, it may be contained in a ratio of 50:50, so the conductivity of the layer can be further improved.

Meanwhile, in the light of the improvement of conductivity and non-resistance, the aqueous dispersion may contain 1 to 5 wt % of the PEDOT-PSS polymer composed of the compositional ratios as described above, less than 0.1 wt % of the surfactant, and 94 to 99 wt % of water.

The aqueous dispersion containing the PEDOT-PSS polymer may be formed using the method of forming the conductive layer which was well known in the relevant technical field, for example, the vacuum deposition method, the sputtering method, the ion plating method, the spray heat decomposition method, the chemical plating method, the electro-plating method, the wet coating method, and the bar coating method or the combination thereof.

Among these methods, in particular, the bar coating method may be used in the light of the formation speed and productivity of the linear interconnecting structure.

Furthermore, a coating thickness of the aqueous dispersion including the PEDOT-PSS polymer before it becomes dry may be formed in a range of 5 to 10 μm. When the coating thickness is formed in the range of less than 5 μm, the problems of conductivity and structural stability occur. When the coating thickness is formed in the range of less than 10 μm, the problems of haze and bluish occur.

Furthermore, the coating layer of the aqueous dispersion including the PEDOT-PSS polymer is formed as a layer through drying it. At this time, the drying may be performed by provisionally drying the coating layer for 5 to 40 seconds at the temperature of 100° C. to 160° C.

The aqueous dispersion including the PEDOT-PSS polymer may be formed as multi layers by coating the linear interconnecting structure layer with the aqueous dispersion and drying it more than one time, several times, thereby being capable of more improving optical and electrical properties.

The transparent conductive film according to the present exemplary embodiment of the invention which further forms the PEDOT-PSS layer on the linear interconnecting structure layer may have more improved mechanical properties through drying the film later.

At this time, the drying of the film may be performed for 5 to 40 seconds at the temperature of 100° C. to 160° C. More preferably, the drying may be performed for 20 to 30 minutes at a temperature of 120° C. to 140° C.

The transparent conductive film produced by the method as described above may have excellent flexibility, color sense and transparency while having conductivity, and haze and non-resistant properties which show the same level as the conventional conductive film. Furthermore, the transparent conductive film does not require additional processes or structural changes of the conventional film, thereby being capable of producing it with a lower cost.

Meanwhile, the transparent conductive film as described above may be useful as the touch panel, in particular, an upper substrate and/or a lower substrate of a resisting film type touch panel. The resisting film type touch panel may be configured such that a pair of transparent conductive films is disposed to align by interposing spacers therebetween. When the upper panel is pressurized with the fingers or a pen, while the transparent conductive films are bended, the conductive layers of the upper substrate and the lower substrate come into contact with each other to apply an electric current, thereby detecting a position.

Meanwhile, as described above, since the transparent conductive film according to the present exemplary embodiment of the invention has excellent conductive and transparency, when the transparent conductive film according to the present exemplary embodiment of the invention is used as an upper substrate and a lower substrate of the touch panel, the touch panel having more excellent transparency and flexibility can be implemented.

Meanwhile, the touch panel according to the present exemplary embodiment of the invention as described above may be used in a state of being mounted in a display device such as an LCD device, a PDP, an LED, an OLED or an E-Paper device.

Hereinafter, the present invention will be specifically explained based on detailed examples.

### Example 1

The linear interconnecting structure layer having a thickness of about 7 μm was formed by producing a linear interconnecting structure ink including a linear interconnecting structure of 0.1 wt %, water of 99 wt %, a thickener of 0.5 wt %, and a surfactant of 0.0005 wt %, and thereafter bar-coating any one surface of the PET film having a thickness of 188 μm of Hangsung Industry Co., Ltd. (product No.: HA450-188-0-188A-H) with the linear interconnecting structure ink, and then provisionally drying it for 30 seconds at a temperature of 130° C.

The PEDOT-PSS layer having a thickness of about 7 μm was formed by producing an aqueous dispersion composed of a polymer of 2 wt % including PEDOT-PSS(a weight ratio of 1:1), water of 97 wt %, and a surfactant of 0.05 wt %, and thereafter bar-coating the linear interconnecting structure layer with the aqueous dispersion, and then provisionally drying it for 30 seconds at a temperature of 130° C. using a dryer.

After that, the transparent conductive film was produced by putting the film in which the conductive layer is formed into an oven, and drying it for 10 minutes at a temperature of 120° C.

### Example 2

In example 2, the transparent conductive film was produced by the same method as example 1 except for drying the film for 30 minutes at a temperature of 140° C.

### Comparative Example 1

In comparative example 1, the transparent conductive film was produced by the same method as example 1 except for coating the PET film with an ITO layer instead of the linear interconnecting structure layer and the PEDOT-PSS layer.

### Comparative Example 2

In comparative example 2, the transparent conductive film was produced by the same method as example 1 except for not forming the PEDOT-PSS layer in example 1.

The following optical and electrical properties concerning the transparent conductive films produced by the above examples and comparative examples were evaluated, and the results thereof are described in Table 1.

### Experimental Example 1

### Evaluation of Haze

Haze, transmittance (T) and b* values all were measured using a haze meter.

### Experimental Example 2

### Evaluation of Transmittance (T)

Transmittance concerning the transparent conductive films prepared in above examples 1 and 2 and comparative examples 1 and 2 was measured using an US-Vis spectrometer. The results thereof are shown in Table 1 below.

### Experimental Example 3

### Evaluation of Color Coordinate (b*)

Color Coordinate concerning the transparent conductive films prepared in above examples 1 and 2 and comparative examples 1 and 2 was measured using a CIE color coordinate measuring method and a D 75 source. The results thereof are shown in Table 1 below.

### Experimental Example 4

### Evaluation of Surface Resistance (R)

Surface resistance concerning the transparent conductive films prepared in above examples 1 and 2 and comparative examples 1 and 2 was measured using a 4-probe measurement method (i.e. Loresta EP MCP-T360). The measured results are shown in Table 1.

TABLE 1

| | | | Comparative | Comparative |
|---|---|---|---|---|
| | Example 1 | Example 2 | Example 1 | Example 2 |
| Haze (%) | 0.54 | 0.48 | 0.64 | 0.81 |
| T (%) | 90.06 | 89.72 | 89.73 | 90.96 |
| b* | 0.65 | 0.61 | 1.02 | 0.73 |
| R (k/sq) | 1.01 | 0.18 | 0.16 | 18.47 |

As shown in [Table 1] above, the transparent conductive film according to the present exemplary embodiment of the invention showed more excellent performances compared to a film (comparative example 1) using transparent ITO with respect to the light of haze and transparency. Furthermore, the transparent conductive film has more improved haze and transmittance compared to a film including only the linear interconnecting structure layer (comparative example 2), showing in particular remarkably improved results concerning surface resistance. Thus, electrical and optical properties of the transparent conductive film according to the present exemplary embodiment of the invention are excellent. Of course the transparent conductive film which is profitable in the light of flexibility and an economic problem by replacing ITO with it can be provided.

As previously described, in the detailed description of the invention, having described the detailed exemplary embodiments of the invention, it should be apparent that modifications and variations can be made by persons skilled without deviating from the spirit or scope of the invention. Therefore, it is to be understood that the foregoing is illustrative of the present invention and is not to be construed as limited to the specific embodiments disclosed, and that modifications to the disclosed embodiments, as well as other embodiments, are intended to be included within the scope of the appended claims and their equivalents.

1. A transparent conductive film, comprising:
a transparent film; and
a conductive layer formed on one surface of the transparent film, wherein the conductive layer comprises: a linear interconnecting structure layer and a PEDOT(poly-3,4-ethylene dioxythiophene)-PSS(polystyrenesulfonate)-layer.

2. The transparent conductive film of claim 1, wherein the linear interconnecting structure layer is formed on one surface of the transparent film, and the PEDOT(poly-3,4-ethylene dioxythiophene)-PSS(polystyrenesulfonate) layer is formed on the linear interconnecting structure layer.

3. The transparent conductive film of claim 1, wherein the linear interconnecting structure layer is composed of two or more multi layers.

4. The transparent conductive film of claim 1, wherein the PEDOT(poly-3,4-ethylene dioxythiophene)-PSS(polystyrenesulfonate) layer is composed of two or more multi layers.

5. The transparent conductive film of claim 1, wherein the linear interconnecting structure layer has a thickness of 5 to 10 μm before it becomes dry.

6. The transparent conductive film of claim 1, wherein the PEDOT(poly-3,4-ethylene dioxythiophene)-PSS(polystyrenesulfonate) layer has a thickness of 5 to 10 μm before it becomes dry.

7. The transparent conductive film of claim 1, wherein the PEDOT(poly-3,4-ethylene dioxythiophene)-PSS(polystyrenesulfonate) layer contains PEDOT(poly-3,4-ethylene dioxythiophene) and PSS(polystyrenesulfonate) in a ratio of 1:1.

8. The transparent conductive film of claim 7, wherein the PEDOT(poly-3,4-ethylene dioxythiophene)-PSS(polystyrenesulfonate) layer further includes a surfactant.

9. (canceled)

10. The transparent conductive film of claim 1, wherein the linear interconnecting structure layer further includes a thickener and a surfactant.

11. A touch panel, comprising the transparent conductive film of claim 1.

12. A display device, comprising the touch panel of claim 11.

13. The display device of claim 12, wherein the display device is an LCD device, a PDP, an LED, an OLED or an E-paper device.

14. A method of manufacturing a transparent conductive film, comprising forming a conductive layer comprising a linear interconnecting structure layer and a PEDOT(poly-3,4-ethylene dioxythiophene)-PSS(polystyrenesulfonate) layer.

15. The method of claim 14, wherein the forming of the conductive layer comprises: forming the linear interconnecting structure layer on one surface of the transparent film; and forming the PEDOT-PSS layer on the linear interconnecting structure layer.

16. The method of claim 15, wherein the forming of the linear interconnecting structure layer is performed by coating one surface of the transparent film with a linear interconnecting structure ink, water, a thickener, and a surfactant; and provisionally drying it for 5 to 40 seconds at a temperature of 100° C. to 160° C.

17. The method of claim 16, wherein the forming of the linear interconnecting structure layer is performed more than one time.

18. The method of claim 15, wherein the forming of the PEDOT-PSS layer is performed by coating the linear interconnecting structure layer with a PEDOT aqueous dispersion including PEDOT, PSS, water, and a surfactant, and provisionally drying it for 5 to 40 seconds at a temperature of 100° C. to 160° C.

19. The method of claim 18, wherein the forming of the PEDOT-PSS layer is performed more than one time.

20. The method of claim 14, further comprising drying the film after the forming of the conductive layer including the linear interconnecting structure layer and the PEDOT-PSS layer.

21. The method of claim 20, wherein the drying of the film is performed for 5 to 40 seconds at a temperature of 100° C. to 160° C.
